(19) United States
(12) Patent Application Publication
(10) Pub. No.: US 2025/0334636 A1
(43) Pub. Date: Oct. 30, 2025

(54) DEVICE AND METHOD FOR INSPECTING SLOT TAP OF MOTOR CORE

(71) Applicant: ADVANCED DIGITAL TECHNOLOGY CO., LTD., Ansan-si (KR)

(72) Inventors: Sang Tae KIM, Seongnam-si (KR); Won Wook SONG, Daegu (KR); Sang Hyun LEE, Siheung-si (KR)

(21) Appl. No.: 19/186,665

(22) Filed: Apr. 23, 2025

(30) Foreign Application Priority Data
Apr. 24, 2024 (KR) 10-2024-0054926

(51) Int. Cl. G01R 31/34; G01M 11/00

(52) U.S. Cl. CPC G01R 31/346; G01M 11/30

(57) ABSTRACT

Disclosed are a device and a method for inspecting a slot tap of a motor core to accurately inspect a slot tap of a non-molding type motor core in a non-contact manner, and the method for inspecting the slot tap of the motor core is implemented through the process that initializes the device for inspecting the slot tap of the motor core, moves the optical sensor to an inspection position using a servo motor, projects light onto a slot of the motor core using the optical sensor, converts reflected light into an electrical signal to obtain tap detection data, analyzes the obtained tap detection data, generates an analysis result as a tap inspection result to store the analysis result in a memory, and visually displays the tap inspection result.

### BACKGROUND OF THE INVENTION

### 1. Field of the Invention

The present invention relates to an inspection of a slot tap of a motor core, and more particularly, to a device and a method for inspecting a slot tap of a motor core to accurately inspect a slot tap of a non-molding type motor core in a non-contact manner.

### 2. Description of the Related Art

In general, a motor is configured to transmit a rotational power of a rotor to a rotary shaft to allow the rotary shaft to drive a load, and has a motor core composed of the rotor, a stator, a copper wire, a support, a permanent magnet and the like.

In the above motor, the rotor rotates by electromagnetic interaction with the stator. A coil is wound on the stator, and the rotor rotates relative to the stator when a current is applied to the coil.

The stator is formed with multiple slots, and each slot is formed with multiple taps.

One of approaches for checking a presence of a tap formed in a core slot includes directly detecting an eddy current, which is a current generated by electromagnetic induction in a conductor placed in a magnetic field changed over time.

However, the approach of detecting the eddy current for checking the presence of a tap is a scheme of detecting a direct eddy current. Thus, there is a disadvantage in that it may be complicated to direct detect the eddy current, in a structure in which multiple slots are provided in one core and multiple taps are provided in each slot.

Particularly, there is a disadvantage in that a sensor is required to be mounted because the sensor for detecting a current is mounted on the motor core to directly detect the eddy current, and there is a disadvantage in that it takes a long time to inspect the slot tap and the inspection of the slot tap is complicated.

In addition, the eddy current scheme has limitations in accurately inspecting the slot tap because an eddy current loss may occur when heat is generated within the conductor.

Therefore, a technology is needed for simply and accurately inspecting the presence of a core tap in a non-contact manner without mounting a sensor when inspecting the core slot tap.
(Patent Document 1) Korean Patent Registration No. 10-0845850 (MOTOR)
(Patent Document 2) Korean Patent Registration No. 10-0937425 (MOTOR)
(Patent Document 3) Korean Patent Registration No. 10-1306768 (AUTOMATIC TAP INSPECTION DEVICE USING CURRENT RESISTANCE OF MOTOR)
(Patent Document 4) Korean Unexamined Patent Publication No. 10-2014-0137420 (DEVICE AND METHOD FOR INSPECTION OF STATOR CORE OF ELECTRICAL MACHINE)

### SUMMARY OF THE INVENTION

Accordingly, in order to solve various problems occurring during inspection of the above-described general motor core, the present invention provides a device and a method for inspecting a slot tap of a motor core to accurately inspect a slot tap of a non-molding type motor core in a non-contact manner.

The present invention further provides a device and a method for inspecting a slot tap of a motor core to inspect the slot tap of the motor core in a non-contact manner using light, so as to accurately detect a presence of a tap, a tap-omission position upon omission of the tap, a distance of a space section in the middle of the slot.

In order to achieve the above-mentioned objects, “a device for inspecting a slot tap of a motor core” according to the present invention includes:
an optical sensor for projecting light onto a slot of the motor core and converting reflected light into an electrical signal to output the signal as an inspection signal;
an amplifying unit for amplifying the inspection signal output from the optical sensor to a predetermined level;
an analog/digital converter for converting an analog inspection signal amplified in the amplifying unit into digital inspection data;
a tap presence detection unit for detecting whether a tap is formed based on the digital inspection data output from the analog/digital converter to output tap detection data;
a tap defect determination unit for determining whether the tap is defective based on the tap detection data to generate a tap detection result; and
a tap detection result display unit for visually displaying the tap detection result generated by the tap defect determination unit.

Preferably, the optical sensor may use an optical fiber sensor and receive reflected light while projecting light using the optical fiber sensor in a length direction of the slot.

Preferably, the tap presence detection unit may detect a presence of the tap by comparing the received digital inspection data with previously registered reference data to determine whether the tap is formed.

Preferably, the tap defect determination unit may check tap number information included in the tap detection data detected by the tap presence detection unit to determine whether the tap formation of the slot is defective.

In addition, “a device for inspecting a slot tap of a motor core” according to the present invention further includes: a tap distance calculation unit for computing an inter-tap distance based on the digital inspection data output from the analog/digital converter to obtain tap distance calculation data and transmitting the obtained tap distance calculation data to the tap defect determination unit, wherein
the tap defect determination unit determines whether the tap is defective based on the tap detection data and the tap distance calculation data, and uses the tap distance calculation data to check a tap-omission position and a section distance of a section in which the tap is absent.

In addition, “a method for inspecting a slot tap of a motor core” according to the present invention includes:
(a) a step of initializing a device for inspecting the slot tap of the motor core and using a servo motor to move an optical sensor to an inspection position;
(b) a step of using the optical sensor to project light onto a slot of the motor core and converting reflected light into an electrical signal to obtain tap detection data;
(c) a step of analyzing the obtained tap detection data, generating an analysis result as a tap inspection result, and storing the generated analysis result in a memory; and
(d) a step of visually displaying the results of the tap inspection result.

Preferably, step (b) may include
receiving the reflected light while projecting light using an optical fiber sensor in a length direction of the slot.

Preferably, step (c) may include
checking tap number information included in the tap detection data to determine whether the tap formation of the slot is defective, and checking a tap-omission position and a section distance of a section in which the tap is absent, based on inter-tap distance calculation data included in the tap detection data.

According to the present invention, a slot tap of a non-molding type motor core can be accurately inspected in a non-contact manner.

In addition, according to the present invention, the slot tap of the motor core is inspected in a non-contact manner using light, so that a presence of a tap, a tap-omission position upon omission of the tap, a distance of a section formed therein with a space in the middle of the slot can be accurately detected.

In addition, according to the present invention, the slot tap of the motor core can be inspected in a non-contact manner using light, so that the slot tap can be conveniently and quickly inspected compared to the existing slot tap inspection scheme using direct current detection with the inconvenience in sensor installation.

### BRIEF DESCRIPTION OF THE DRAWINGS

FIG. 1 is a perspective view of a device for inspecting a slot tap of a motor core according to the present invention.

FIG. 2 is one side view of FIG. 1.

FIG. 3 is an exemplary configuration view of a motor core as a subject to be inspected of the present invention.

FIG. 4 is an enlarged view of one slot of FIG. 3.

FIG. 5 is a block diagram of the device for inspecting the slot tap of the motor core according to the present invention.

FIG. 6A is an exemplary view showing a full slot tap inspection screen in the present invention.

FIGS. 6B to 6E are exemplary split screen views in which the full slot tap inspection screen of FIG. 6A is split and displayed.

FIG. 7 is a flow chart showing a method for inspecting a slot tap of a motor core according to the present invention.

### DETAILED DESCRIPTION OF THE INVENTION

Hereinafter, a device and a method for inspecting a slot tap of a motor core according to the exemplary embodiments of the present invention will be described with reference to the accompanying drawings.

The terms or words used in the present invention described below will not be construed as limited to a conventional or lexical meaning, and will be construed as the meanings and concepts based on the principle that “an inventor may define the concept of the term properly in order to describe the invention in the best way”.

Accordingly, the embodiments described herein and the configurations shown in the drawings are merely preferred embodiments according to the present invention, and do not represent all of the technical ideas of the present invention. Therefore, it will be understood that various equivalents and modifications may be substituted therefor at the time of filing of the present application.

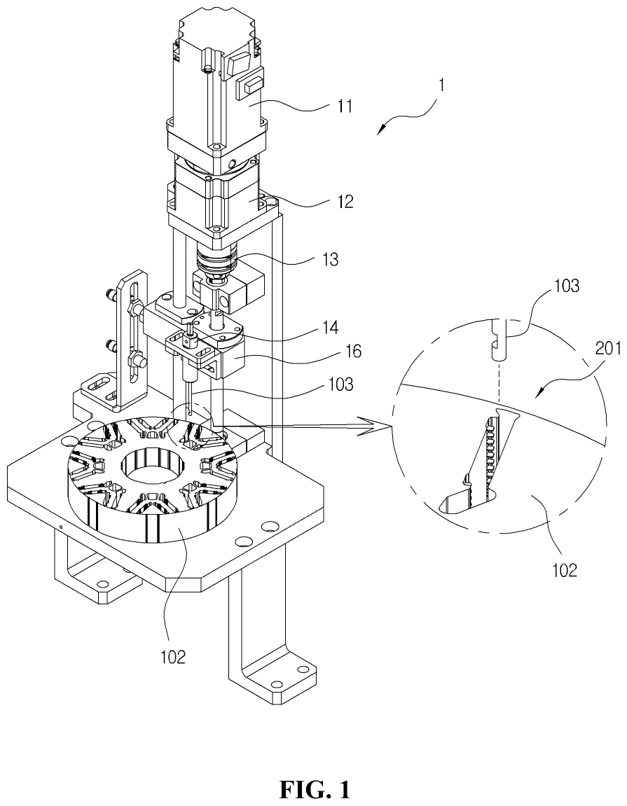

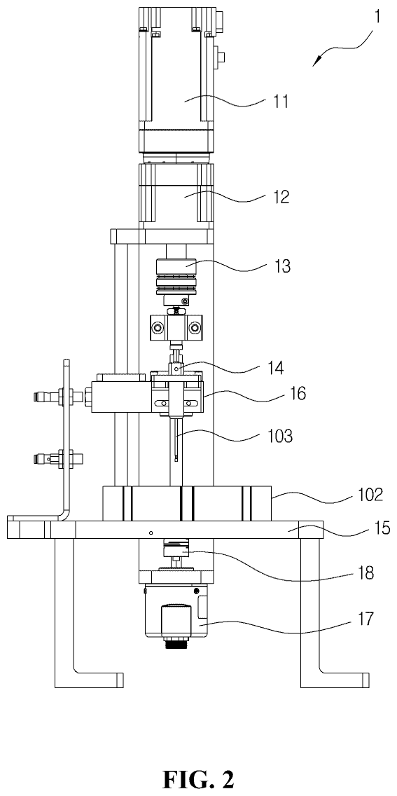

FIG. 1 is a perspective view of a device for inspecting a slot tap of a motor core according to a preferred embodiment of the present invention; and FIG. 2 is one side view of FIG. 1.

A device 1 for inspecting a slot tap of a motor core according to the present invention includes a servo motor 11 for moving an optical sensor 103 up and down or left and right, a reducer 12, a sensor holder 14 for fixing the optical sensor, a coupling 13 for coupling the sensor holder 14 to the reducer 12, an encoder 17 provided below a motor core 102 to detect a movement amount of the motor core 102, an encoder coupling 18 for coupling the encoder 17 to a plate 15 of the inspection device, an encoder plate 16, and the like.

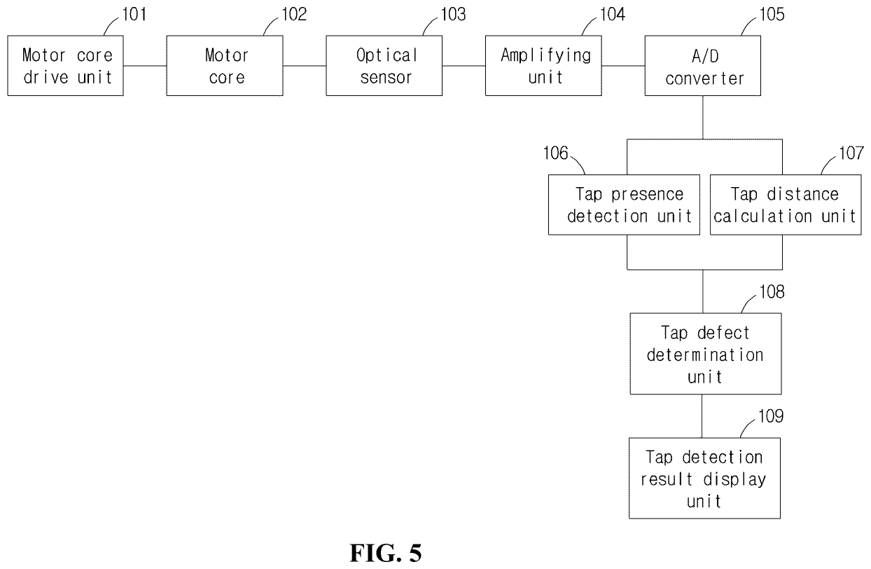

In addition, although not shown in the drawing, a processing device as in FIG. 5 for receiving and processing a slot tap inspection signal detected by the optical sensor 103 may be provided in conjunction with the device 1 for inspecting a slot tap of a motor core.

FIG. 5 is a block diagram of the device 1 for inspecting the slot tap of the motor core according to the present invention, and may include a motor core drive unit 101, a motor core 102, an optical sensor 103, an amplifying unit 104, an analog/digital converter 105, a tap presence detection unit 106, a tap distance calculation unit 107, a tap defect determination unit 108, and a tap detection result display unit 109.

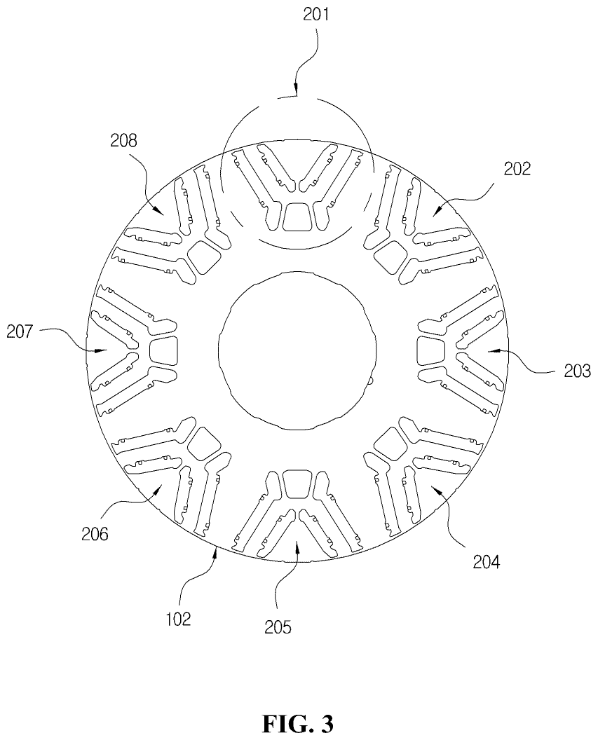

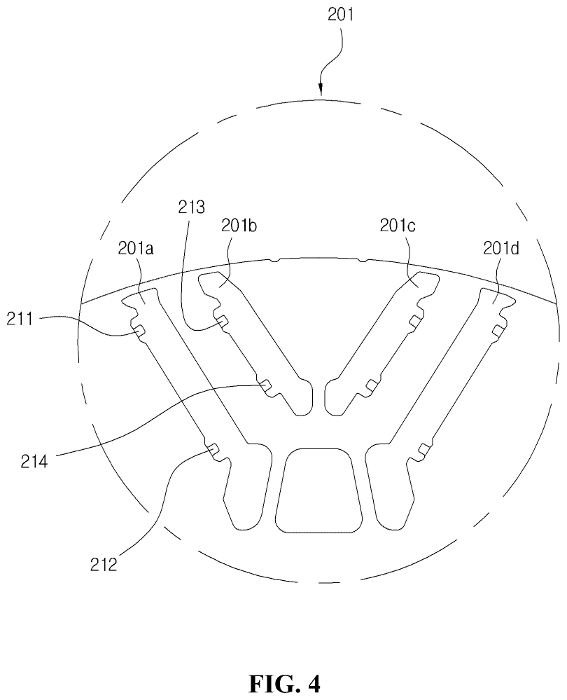

The motor core drive unit 101 serves to rotate the motor core 102 at a set speed. The optical sensor 103 may move up and down and left and right by the servo motor 11, and inspect whether a tap is formed in each slot of all slot portions, such as 201 to 208 of FIG. 3, provided in the motor core 102.

Herein, 36 slots is provided in one core, and 24 taps are formed in each slot. The formation position of each slot and the number of taps provided in the slot are the same. Thus, hereinafter, only one slot portion 201, one slot 201a, and taps, such as 211 and 212, provided in the one slot 201a will be described for the clarity of description.

The optical sensor 103 serves to project light onto a slot, such as 201a, of the motor core 102, and convert reflected light into an electrical signal to output the electrical signal as an inspection signal.

The optical sensor 103 may use an optical fiber sensor to receive the reflected light while projecting light using the optical fiber sensor in a length direction of the slot. In the present invention, the optical fiber sensor is described as an example of the optical sensor. However, the present invention is not limited thereto, and it is apparent that any optical sensor capable of using light to detect a subject to be inspected in a non-contact manner may also be applied.

The amplifying unit 104 serves to amplify the inspection signal output from the optical sensor 103 to a predetermined level. The optical sensor 103 outputs the inspection signal as a small voltage (or current). Thus, in order to use the inspection signal for inspection, the amplifying unit 104 amplifies and outputs the inspection signal to a preset gain level.

The analog/digital converter 105 serves to convert the analog inspection signal amplified by the amplifying unit 104 into digital inspection data.

The tap presence detection unit 106 serves to detect whether a tap is formed based on the digital inspection data output from the analog/digital converter 105 and output tap detection data.

The tap presence detection unit 106 may detect the presence of the tap by comparing the received digital inspection data with previously registered reference data to determine whether the tap is formed.

The tap distance calculation unit 107 serves to compute an inter-tap distance based on the digital inspection data output from the analog/digital converter 105 to obtain tap distance calculation data and transmit the obtained tap distance calculation data to the tap defect determination unit 108.

The tap defect determination unit 108 serves to determine whether the tap is defective based on the tap detection data to generate a tap detection result.

In addition, the tap defect determination unit 108 may check tap number information included in the tap detection data detected by the tap presence detection unit 106 to determine whether the tap formation of the slot is defective.

In addition, the tap defect determination unit 108 may determine whether the tap is defective based on the tap detection data and the tap distance calculation data, and may use the tap detection data to determine a tap-omission position and check a section distance of a section in which the tap is not formed based on the tap distance calculation data.

The tap detection result display unit 109 serves to visually display the tap detection result generated by the tap defect determination unit 108.

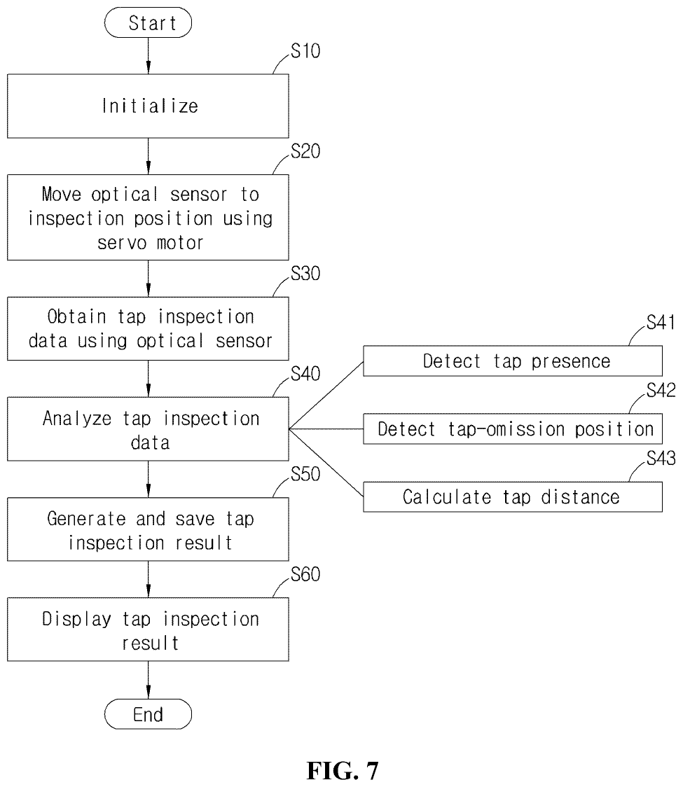

FIG. 7 is a flow chart showing a method for inspecting a slot tap of a motor core according to the present invention, and the method may include (a) steps (S10 to S20) of initializing a device 1 for inspecting the slot tap of the motor core and using a servo motor 11 to move an optical sensor 103 to an inspection position; (b) a step (S30) of using the optical sensor 103 to project light onto a slot of the motor core and converting reflected light into an electrical signal to obtain tap detection data; (c) a step (S40 to S50) of analyzing the obtained tap detection data, generating an analysis result as a tap inspection result, and storing the generated analysis result in a memory; and (d) a step (S60) of visually displaying the results of the tap inspection result.

Step (b) may include receiving the reflected light while projecting light using an optical fiber sensor in a length direction of the slot.

In addition, step (c) may include checking tap number information included in the tap detection data to determine whether the tap formation of the slot is defective, and using the tap detection data to determine a tap-omission position, and checking a section distance of a section in which the tap is not formed based on the tap distance calculation data.

The device and the method for inspecting a slot tap of a motor core configured in the above manner according to the preferred embodiment of the present invention will be described in detail as follows.

First, the device 1 for inspecting a slot tap of a motor core is initialized. In other words, initialization, such as activating an inspection program for inspection, is performed (S10).

Next, the motor core 102 as a subject to be inspected is placed in the inspection position, and the motor core drive unit 101 drives the motor core 102 to rotate and move to the inspection position according to the control of a controller (not shown in the drawing, and may be implemented by a personal computer (PC) or a control board) that comprehensively controls the device 1 for inspecting a slot tap of a motor core.

Next, the servo motor 11 operates in response to the control of the controller to move the optical sensor 103 to the inspection position (S20).

When the optical sensor 103 has moved to the inspection position and the inspection starts, the optical sensor 103 projects light onto a slot, such as 201a, of the motor core 102, and converts reflected light into an electrical signal to output the electrical signal as an inspection signal. The optical sensor 103 may use an optical fiber sensor to receive the reflected light while projecting light using the optical fiber sensor in a length direction of the slot. The optical fiber sensor serving as the optical sensor may project an optical signal perpendicular to the slot, or may be formed at a similar angle to the slot to project light onto the slot and reflect the light at an oblique angle. The reason for installing the optical sensor to be perpendicular or oblique to the slot is to optimize the overall inspection space and optimally receive the reflected light.

The inspection signal (micro voltage or micro current) output in the above manner is amplified to a predetermined level through the amplifying unit 104 equipped in the control board or controller.

The amplified inspection signal is converted into digital inspection data through the analog/digital converter 105 and transmitted to the tap presence detection unit 106 and the tap distance calculation unit 107 (S30).

The tap presence detection unit 106 and the tap distance calculation unit 107 obtain and analyze the received digital inspection data as tap inspection data (S40).

The tap inspection data may include analysis (S41) for detecting whether a tap is formed, analysis (S42) for detecting a tap-omission position, and analysis (S43) for calculating a tap distance.

For example, the tap presence detection unit 106 compares the digital inspection data output from the analog/digital converter 105 with previously registered reference data to determine tap formation, thereby detecting whether a tap is formed. In other words, light is projected in the length direction to the slot 201a, the reflected light is received in real time, and data received in real time is digitized, thereby becoming the digital inspection data. As for the optical signal, the intensity of the reflected light differs depending on whether a tap is present or not in the slot. The signal of reflected light is displayed as a voltage value (or current value), and the voltage value varies depending on the presence or absence of the tap. In other words, the intensity of reflected light varies depending on distance, and the distance of the reflected light varies depend on the section in which the tap is present and the section in which the tap is not present. This results in differences in the intensity of the reflected light.

Accordingly, when the digital inspection data formed by digitizing the detected signal is compared with the reference data prepared based on the presence of a tap, the formation of a tap may be easily detected. In addition, after detection on whether the tap is formed, the number of taps formed for one slot is counted based on the above detection to generate tap detection data and transmit the generated tap detection data to the tap defect determination unit 108.

In addition, the tap distance calculation unit 107 computes a distance between taps based on the digital inspection data output from the analog/digital converter 105 and transmits the obtained tap distance calculation data to the tap defect determination unit 108.

The distance between taps may be calculated by calculating a distance between a first tap and a next tap, calculating a distance between the next tap and a tap after the next tap, and the like, so that the distances between taps from the first tap to the last tap may be calculated.

The tap defect determination unit 108 determines whether the tap is defective based on the tap detection data, and determines whether the tap formation of the slot is defective by checking the number of taps included in the tap detection data. In addition, the tap distance calculation data is used to determine a tap-omission position. Since the distance between taps is already fixed within a predetermined range, the tap distance information beyond the predetermined range after analyzing the tap distance calculation data is information about a state in which a tap is absent. Accordingly, when the information about the state of the absent tap is detected through the tap distance information while the taps are counted sequentially, the absent tap may be checked as the tap-omission position. In addition, the distance information between taps is also used to measure an interval distance between omitted taps.

The tap defect determination unit 108 generates the tap defect data, the tap-omission position and the tap distance information, which are analyzed and obtained in the above manner, as tap inspection results, and stores the data in an internal memory (S50).

Next, the tap defect determination unit 108 visually displays the generated tap inspection results through the tap detection result display unit 109 (S60).

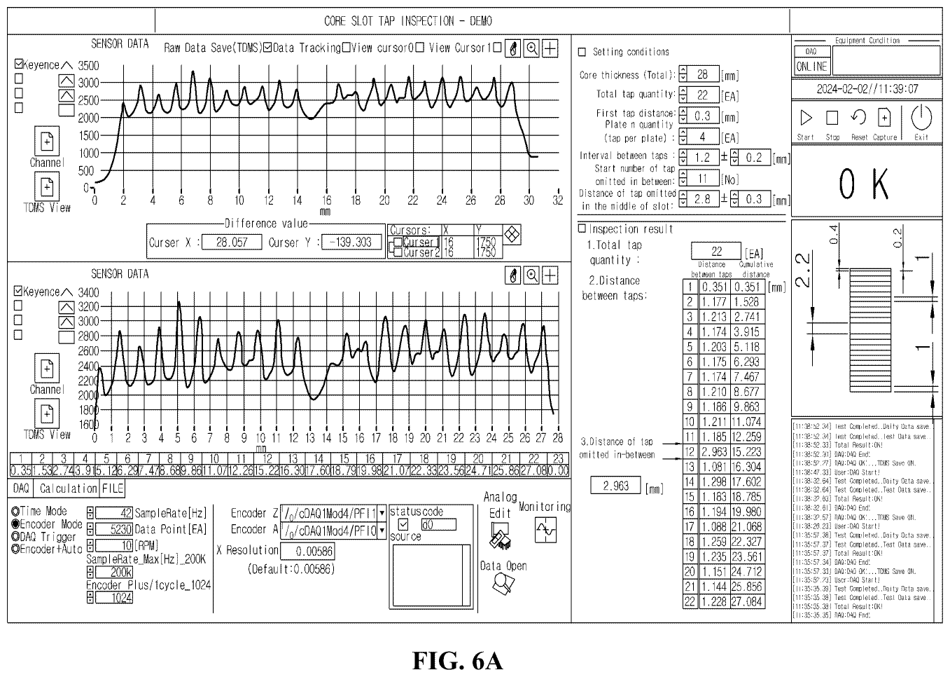

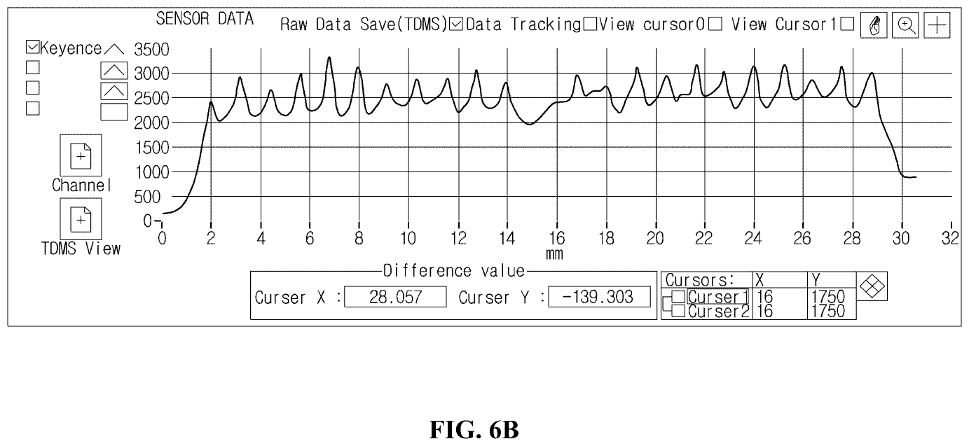

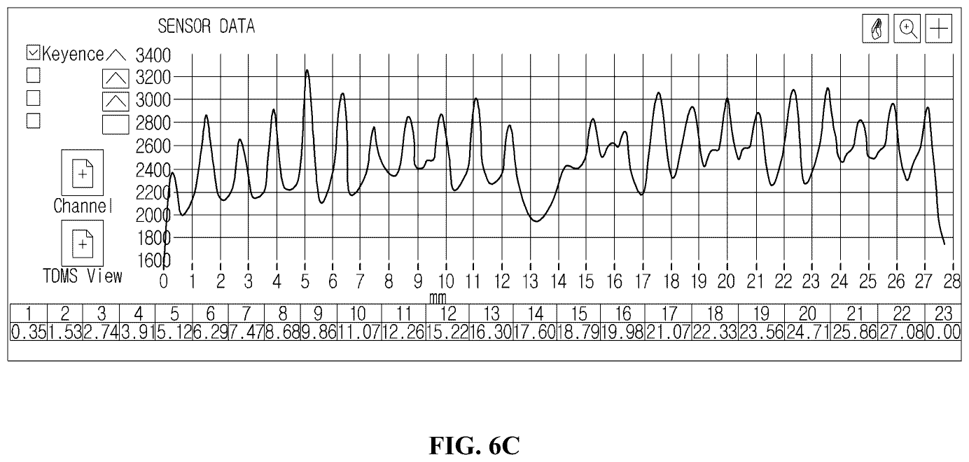

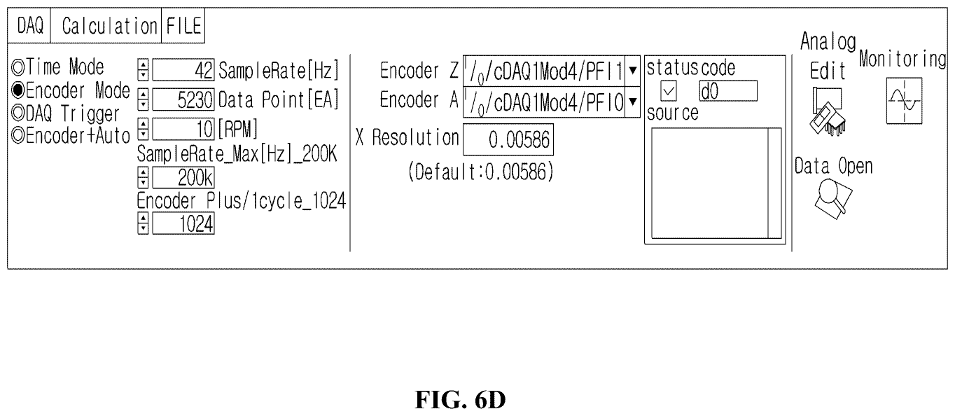

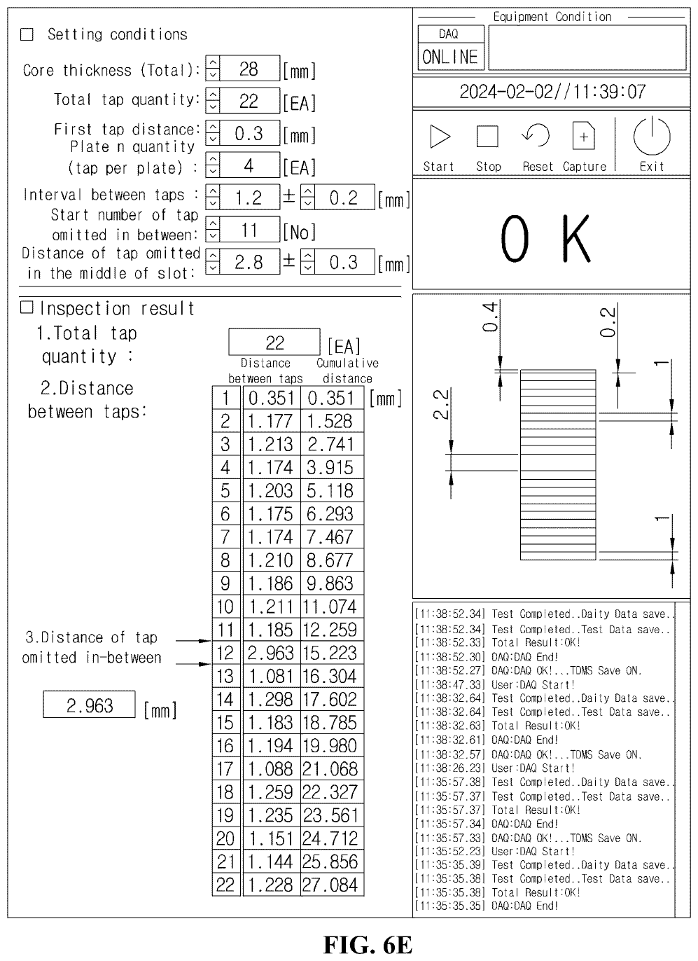

FIG. 6A is an exemplary view showing a full slot tap inspection screen in the present invention, and FIGS. 6B to 6E are exemplary split screen views in which the full slot tap inspection screen of FIG. 6A is split and displayed. When a core thickness, a total tap quantity, a first tap distance, a plate n quantity (tap per plate), a tap interval, a start number of taps omitted in between, a distance of taps omitted in between, and the like are set, the slot tap is automatically inspected using the non-contact optical inspection scheme as described above, and the inspection results are visually displayed through the tap detection result display unit 109, so that the inspector may recognize, in real time, which core has a problem and what the problem is.

According to the present invention as described above, a slot tap of a non-molding type motor core can be accurately inspected in a non-contact manner.

In addition, according to the present invention, the slot tap of the motor core is inspected in a non-contact manner using light, so that a presence of a tap, a tap-omission position upon omission of the tap, a distance of a section formed therein with a space in the middle of the slot can be accurately detected.

In addition, according to the present invention, the slot tap of the motor core can be inspected in a non-contact manner using light, so that the slot tap can be conveniently and quickly inspected compared to the existing slot tap inspection scheme using direct current detection with the inconvenience in sensor installation.

Although a few embodiments of the present invention have been shown and described, the present invention is not limited to the described embodiments. Instead, it would be appreciated by those skilled in the art that changes may be made to these embodiments without departing from the principles and spirit of the invention, the scope of which is defined by the claims and their equivalents.

What is claimed is:

1. A device for inspecting a slot tap of a motor core, the device comprising:
an optical sensor for projecting light onto a slot of the motor core and converting reflected light into an electrical signal to output the signal as an inspection signal;
an amplifying unit for amplifying the inspection signal output from the optical sensor to a predetermined level;
an analog/digital converter for converting an analog inspection signal amplified in the amplifying unit into digital inspection data;
a tap presence detection unit for detecting whether a tap is formed based on the digital inspection data output from the analog/digital converter to output tap detection data;
a tap defect determination unit for determining whether the tap is defective based on the tap detection data to generate a tap detection result; and
a tap detection result display unit for visually displaying the tap detection result generated by the tap defect determination unit.

2. The device of claim 1, wherein the optical sensor uses an optical fiber sensor and receives the reflected light while projecting light using the optical fiber sensor in a length direction of the slot.

3. The device of claim 1, wherein the tap presence detection unit detects a presence of the tap by comparing the received digital inspection data with previously registered reference data to determine whether the tap is formed.

4. The device of claim 1, wherein the tap defect determination unit checks tap number information included in the tap detection data detected by the tap presence detection unit to determine whether the tap formation of the slot is defective.

5. The device of claim 1, further comprising:
a tap distance calculation unit for computing an inter-tap distance based on the digital inspection data output from the analog/digital converter to obtain tap distance calculation data and transmitting the obtained tap distance calculation data to the tap defect determination unit, wherein
the tap defect determination unit determines whether the tap is defective based on the tap detection data and the tap distance calculation data, and uses the tap distance calculation data to check a tap-omission position and a section distance of a section in which the tap is absent.

6. A method for inspecting a slot tap of a motor core using a device for inspecting the slot tap of the motor core according to claim 1, the method comprising:
(a) a step of initializing a device for inspecting the slot tap of the motor core and using a servo motor to move an optical sensor to an inspection position;
(b) a step of using the optical sensor to project light onto a slot of the motor core and converting reflected light into an electrical signal to obtain tap detection data;
(c) a step of analyzing the obtained tap detection data, generating an analysis result as a tap inspection result, and storing the generated analysis result in a memory; and
(d) a step of visually displaying the results of the tap inspection result.

7. The method of claim 6, wherein step (b) includes receiving the reflected light while projecting light using an optical fiber sensor in a length direction of the slot.

8. The method of claim 6, wherein step (c) includes checking tap number information included in the tap detection data to determine whether the tap formation of the slot is defective, and using the tap distance calculation data to check a tap-omission position and a section distance of a section in which the tap is absent.
